(19) United States
(12) Patent Application Publication
(10) Pub. No.: US 2009/0026881 A1
(43) Pub. Date: Jan. 29, 2009

(54) PIEZOELECTRIC FAN, METHOD OF COOLING A MICROELECTRONIC DEVICE USING SAME, AND SYSTEM CONTAINING SAME

(76) Inventors: Hakan Erturk, Phoenix, AZ (US); Ioan Sauciuc, Phoenix, AZ (US)

Correspondence Address: INTEL CORPORATION;c/o INTELLEVATE, LLC, P.O. BOX 52050, MINNEAPOLIS, MN, 55402, US

(21) Appl. No.: 11/828,759

(22) Filed: Jul. 26, 2007

(51) Int. Cl. H01L 41/09; G01R 21/06; G05F 1/10

(52) U.S. Cl. 310/311; 323/204; 324/98

(57) ABSTRACT

A piezoelectric fan comprises a blade (110, 210, 310, 410, 510, 610), a piezoelectric actuator patch (120, 220, 320, 420, 520, 620, 811) adjacent to the blade, and a piezoelectric sensor patch (130, 230, 330, 430, 530, 630, 812) adjacent to one of the piezoelectric actuator patch and the blade. The piezoelectric sensor patch measures a voltage proportional to a deflection of the piezoelectric actuator patch and a deflection of a tip of the blade and uses that voltage to generate an input signal to an active feedback controller (840) that in turn ensures that the oscillation amplitude of the blade satisfies certain cooling specifications.

### FIELD OF THE INVENTION

The disclosed embodiments of the invention relate generally to the thermal management of microelectronic devices, and relate more particularly to piezoelectric fans.

### BACKGROUND OF THE INVENTION

Piezoelectric materials are capable of generating a voltage when subjected to a mechanical strain according to what is known as the piezoelectric effect. The piezoelectric effect also works in reverse, such that a piezoelectric material may be made to change shape slightly when subjected to an externally-applied voltage. Piezoelectric materials have been used as components in piezoelectric cooling fans, where a blade attached to a piezoelectric patch is made to oscillate in order to generate airflow. However, the performance of piezoelectric fans is significantly affected by operating conditions such as altitude, any background airflow, and manufacturing variabilities. The microelectronics industry has thus far not developed a low cost, small size active feedback controller for piezoelectric fans in order to achieve desired deflection and performance at different system boundary conditions and varying operating conditions.

### BRIEF DESCRIPTION OF THE DRAWINGS

The disclosed embodiments will be better understood from a reading of the following detailed description, taken in conjunction with the accompanying figures in the drawings in which:

FIGS. 1-6 are side elevational views of various piezoelectric fans according to embodiments of the invention;

FIG. 7 is a flowchart illustrating a method of cooling a microelectronic device according to an embodiment of the invention;

FIG. 8 is a chart showing an operation of an active feedback controller according to an embodiment of the invention; and

FIG. 9 is a schematic representation of a system including an axial fan according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,”. “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a piezoelectric fan comprises a blade, a piezoelectric actuator patch adjacent to the blade, and a piezoelectric sensor patch adjacent to either the piezoelectric actuator patch or the blade. The piezoelectric sensor patch measures a voltage proportional to a strain caused by a deflection in a system due to the operation of the piezoelectric actuator patch and uses that voltage to generate an input signal to an active feedback controller that in turn adjusts the oscillation amplitude of the blade to satisfy desired cooling specifications. Operation of the piezoelectric fan within the airflow of an axial fan or the like may cause changes in the blade oscillation amplitude. The piezoelectric sensor patch measures these changes and, in conjunction with the active feedback controller, enables adjustments to the piezoelectric fan system that maintain that system within the desired cooling specifications.

Referring now to the drawings, FIG. 1 is a side elevational view of a piezoelectric fan 100 according to an embodiment of the invention. As illustrated in FIG. 1, piezoelectric fan 100 comprises a blade 110, a piezoelectric actuator patch 120 adjacent to blade 110, and a piezoelectric sensor patch 130 adjacent to piezoelectric actuator patch 120. Piezoelectric sensor patch 130 may be thought of as also being adjacent to blade 110, in the sense that piezoelectric sensor patch 130 is in reasonably close proximity to blade 110. It may be seen, however, that in the embodiment illustrated in FIG. 1, piezoelectric sensor patch 130 is physically closer to piezoelectric actuator patch 120 than it is to blade 110. In other embodiments of the invention, at least some of which are illustrated in subsequent figures to be described below, the situation is reversed and piezoelectric sensor patch 130 is physically closer to blade 110 than it is to piezoelectric actuator patch 120. In all embodiments described herein, the piezoelectric sensor patch of the piezoelectric fan being described is adjacent to at least one of the blade and the piezoelectric actuator patch in the sense that the adjacent elements are in reasonably close proximity to each other. Whether the piezoelectric sensor patch is physically closer to the blade or to the piezoelectric actuator patch will be apparent from the depiction of each such embodiment.

In at least one embodiment, piezoelectric sensor patch 130 is capable of generating an electrical signal containing information relating to the operation of piezoelectric fan 100. As an example, piezoelectric actuator patch 120 can cause a deflection that generates a voltage created by a corresponding strain in piezoelectric sensor patch 130, and a voltage pattern supplied to piezoelectric fan 100 can then be adjusted according to this generated voltage in order to achieve certain performance criteria, as further discussed below.

Piezoelectric actuator patch 120 comprises a piezoelectric layer 121 located between electrodes 122 and 123. An adhesive layer 124 is located between electrode 122 and blade 110. Similarly, piezoelectric sensor patch 130 comprises a piezoelectric ceramic layer 131 located between an electrode 132 and an electrode 133. In the illustrated embodiment, an adhesive layer 134 is located between electrode 132 and electrode 123. As an example, adhesive layer 124 and, where present, adhesive layer 134, can be an epoxy layer or the like that can both physically attach components of piezoelectric fan 100 to each other and electrically insulate components of piezoelectric fan 100 from each other or from some other object.

In a different embodiment, adhesive layer 134 is omitted from piezoelectric fan 100, in which case the last electrode layer (i.e., the electrode layer farthest from the blade) would be wired separately in order to capture the measured voltage from piezoelectric sensor patch 130. In this latter embodiment the various layers may all be cofired together, eliminating the need for adhesive layer 134 and possibly leading to an increase in performance. Various piezoelectric fan embodiments illustrated herein have a piezoelectric actuator patch located between a blade and a piezoelectric sensor patch. Although each of these embodiments show an adhesive layer (corresponding to adhesive layer 134) between the piezoelectric actuator patch and the piezoelectric actuator patch, each embodiment could also have a (non-illustrated) variation in which such adhesive layer is omitted, just as adhesive layer 134 may be omitted from piezoelectric fan 100 as was just discussed. In those (non-illustrated) embodiments lacking such adhesive layer, outermost electrodes of the adjacent piezoelectric actuator patch and piezoelectric sensor patch may be in physical contact with each other.

As an example, blade 110 can be made of mylar, plastic, steel or another metal, or the like. As another example, electrodes 122, 123, 132, and 133 can be made of a highly electrically conductive material such as nickel, silver palladium, or the like. In one embodiment, electrodes 122, 123, 132, and 133 have a thickness of between approximately three and approximately eight micrometers. As yet another example, piezoelectric layers 121 and 131 can be made of lead zirconium titanate (PZT) or a lead-free piezoelectric material such as bismuth titanate or the like. Alternatively, piezoelectric layers 121 and 131 can be made of another piezoelectric material, including piezoelectric ceramic and piezoelectric polymers. In one embodiment, piezoelectric layers 121 and 131 each have a thickness no greater than approximately 30 micrometers. In general, piezoelectric sensor patch should be made as thin as possible.

In one embodiment, piezoelectric fan 100 (like piezoelectric fans according to other embodiments of the invention) can include a plurality of blades, including blade 110, that may all be made to oscillate in order to further enhance the piezoelectric fan's thermal management capabilities. In the same or another embodiment, the piezoelectric fans may be made to be compatible with multiple systems, thus reducing costs and increasing efficiency.

As mentioned, FIG. 1 depicts a piezoelectric fan according to a particular embodiment of the invention. It should be noted that in FIG. 1, piezoelectric sensor patch 130 and piezoelectric actuator patch 120 are both located on a first side of blade 110. As suggested above, however, components of a piezoelectric fan can also be arranged in various other physical configurations according to various other embodiments of the invention. Several of these other embodiments will now be described, with reference to accompanying drawing figures. In these figures, electrical connections to power supplies or other components are not shown because they will be well within the understanding of one of ordinary skill in the art.

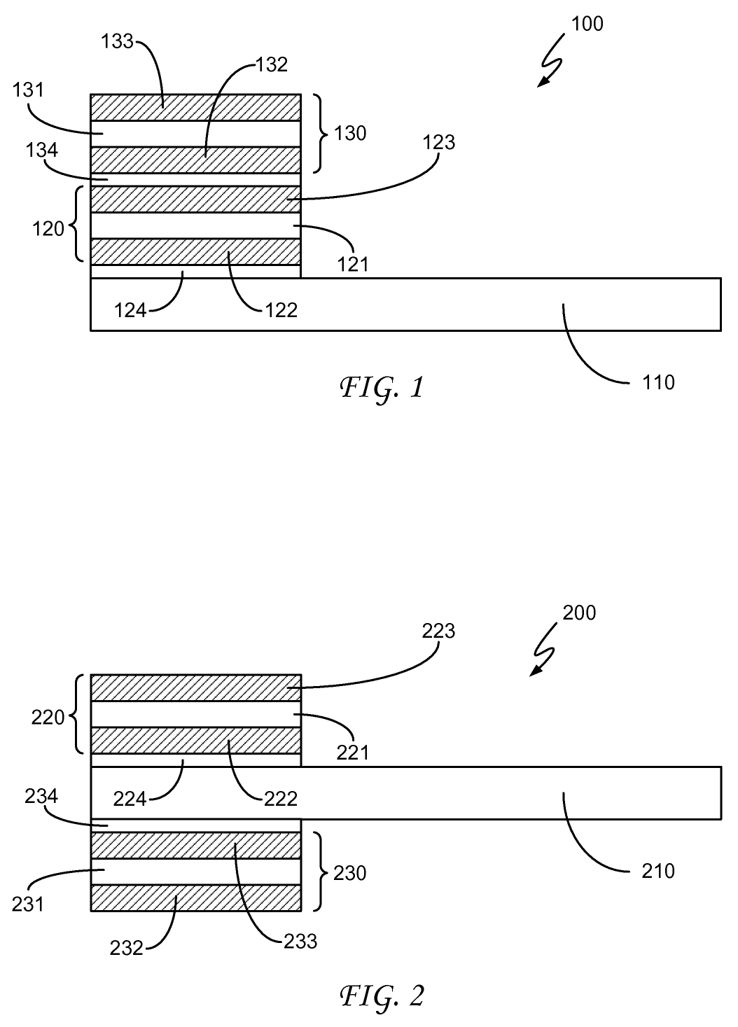

FIG. 2 is a side elevational view of a piezoelectric fan 200 according to an embodiment of the invention. As illustrated in FIG. 2, piezoelectric fan 200 comprises a blade 210, a piezoelectric actuator patch 220 adjacent to blade 210, and a piezoelectric sensor patch 230 adjacent to blade 210. Piezoelectric actuator patch 220 comprises a piezoelectric layer 221 located between an electrode 222 and an electrode 223. An adhesive layer 224 is located between electrode 222 and blade 210. Similarly, piezoelectric sensor patch 230 comprises a piezoelectric layer 231 located between an electrode 232 and an electrode 233. An adhesive layer 234 is located between electrode 233 and blade 210. As illustrated, piezoelectric sensor patch 230 is located on a first side of blade 210 and piezoelectric actuator patch 220 is located on a second side of blade 210 opposite the first side. It should be understood that in a non-illustrated embodiment, piezoelectric sensor patch 230 can be located on the side of blade 210 that in the illustrated embodiment is occupied by piezoelectric actuator patch 220, and vice versa.

As an example, blade 210, piezoelectric actuator patch 220, piezoelectric layer 221, electrode 222, electrode 223, adhesive layer 224, piezoelectric sensor patch 230, piezoelectric layer 231, electrode 232, electrode 233, and adhesive layer 234 can be similar to, respectively, blade 110, piezoelectric actuator patch 120, piezoelectric layer 121, electrode 122, electrode 123, adhesive layer 124, piezoelectric sensor patch 130, piezoelectric layer 131, electrode 132, electrode 133, and adhesive layer 134, all of which are shown in FIG. 1.

FIG. 3 is a side elevational view of a piezoelectric fan 300 according to an embodiment of the invention. As illustrated in FIG. 3, piezoelectric fan 300 comprises a blade 310, a piezoelectric actuator patch 320 adjacent to blade 310, and a piezoelectric sensor patch 330 adjacent to piezoelectric actuator patch 320. Piezoelectric actuator patch 320 comprises a piezoelectric layer 321 located between an electrode 322 and an electrode 323. An adhesive layer 324 is located between electrode 322 and blade 310. Piezoelectric layer 321 is one of a plurality 340 of piezoelectric layers that form a part of piezoelectric actuator patch 320. (Accordingly, piezoelectric actuator patch 320 may be thought of as a “multi-layer actuator.”) Piezoelectric actuator patch 320 further comprises a plurality 350 of electrodes (a plurality that includes electrodes 322 and 323), and, as depicted in FIG. 3, each one of plurality 340 of piezoelectric layers in piezoelectric actuator patch 320 is located between a pair of electrodes of plurality 350 of electrodes. As an example, each one of plurality 340 of piezoelectric layers can be similar to piezoelectric layer 321, and each one of plurality 350 of electrodes can be similar to electrodes 322 and 323.

Piezoelectric sensor patch 330 comprises a piezoelectric layer 331 located between an electrode 332 and an electrode 333. An adhesive layer 334 is located between electrode 332 of piezoelectric sensor patch 330 and one of plurality 350 of electrodes in piezoelectric actuator patch 320. As illustrated, piezoelectric sensor patch 330 and piezoelectric actuator patch 320 are both located on a first side of blade 310. It should be understood that piezoelectric sensor patch 330 and piezoelectric actuator patch 320 could, in a non-illustrated embodiment, be located instead on a different side of blade 310.

As an example, blade 310, piezoelectric actuator patch 320, piezoelectric layer 321, electrode 322, electrode 323, adhesive layer 324, piezoelectric sensor patch 330, piezoelectric layer 331, electrode 332, electrode 333, and adhesive layer 334 can be similar to, respectively, blade 110, piezoelectric actuator patch 120, piezoelectric layer 121, electrode 122, electrode 123, adhesive layer 124, piezoelectric sensor patch 130, piezoelectric layer 131, electrode 132, electrode 133, and adhesive layer 134, all of which are shown in FIG. 1.

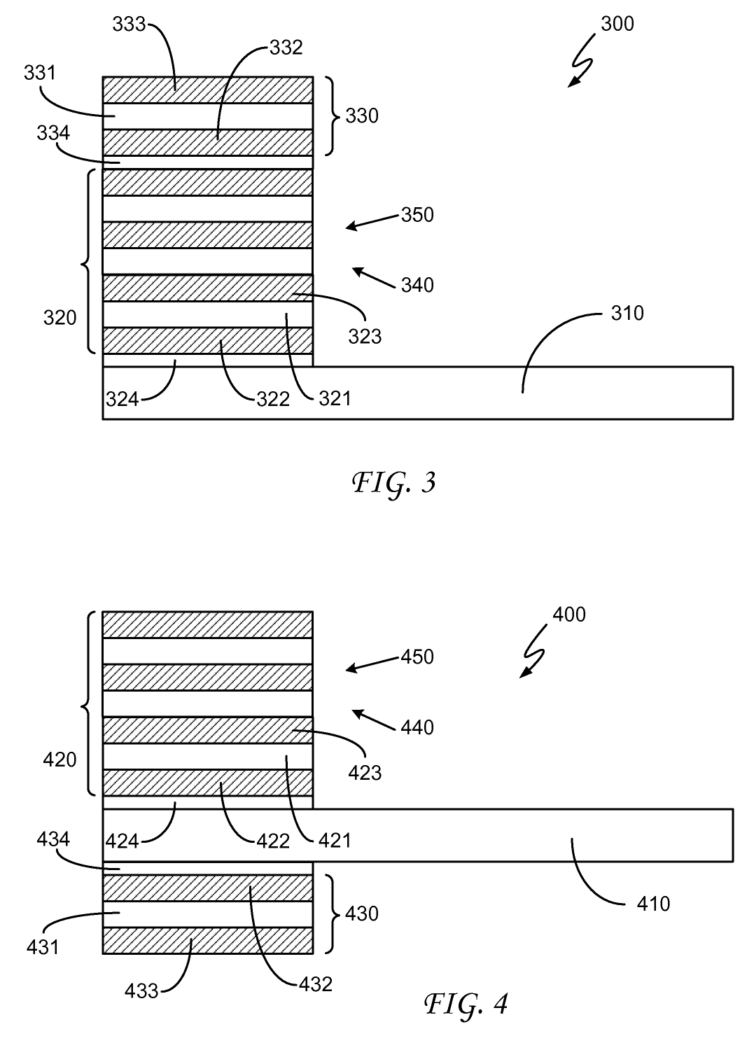

FIG. 4 is a side elevational view of a piezoelectric fan 400 according to an embodiment of the invention. As illustrated in FIG. 4, piezoelectric fan 400 comprises a blade 410, a piezoelectric actuator patch 420 adjacent to blade 410, and a piezoelectric sensor patch 430 adjacent to blade 410. Piezoelectric actuator patch 420 comprises a piezoelectric layer 421 located between an electrode 422 and an electrode 423. An adhesive layer 424 is located between electrode 422 and blade 410. Piezoelectric layer 421 is one of a plurality 440 of piezoelectric layers that form a part of piezoelectric actuator patch 420. Piezoelectric actuator patch 420 further comprises a plurality 450 of electrodes (a plurality that includes electrodes 422 and 423), and, as depicted in FIG. 4, each one of plurality 440 of piezoelectric layers in piezoelectric actuator patch 420 is located between a pair of electrodes of plurality 450 of electrodes. As an example, each one of plurality 440 of piezoelectric layers can be similar to piezoelectric layer 421, and each one of plurality 450 of electrodes can be similar to electrodes 422 and 423.

Piezoelectric sensor patch 430 comprises a piezoelectric layer 431 located between an electrode 432 and an electrode 433. An adhesive layer 434 is located between electrode 432 and blade 410. As illustrated, piezoelectric sensor patch 430 is located on a first side of blade 410 and piezoelectric actuator patch 420 is located on a second side of blade 410 opposite the first side. It should be understood that in a non-illustrated embodiment, piezoelectric sensor patch 430 can be located on the side of blade 410 that in the illustrated embodiment is occupied by piezoelectric actuator patch 420, and vice versa.

As an example, blade 410, piezoelectric actuator patch 420, piezoelectric layer 421, electrode 422, electrode 423, adhesive layer 424, piezoelectric sensor patch 430, piezoelectric layer 431, electrode 432, electrode 433, and adhesive layer 434 can be similar to, respectively, blade 110, piezoelectric actuator patch 120, piezoelectric layer 121, electrode 122, electrode 123, adhesive layer 124, piezoelectric sensor patch 130, piezoelectric layer 131, electrode 132, electrode 133, and adhesive layer 134, all of which are shown in FIG. 1.

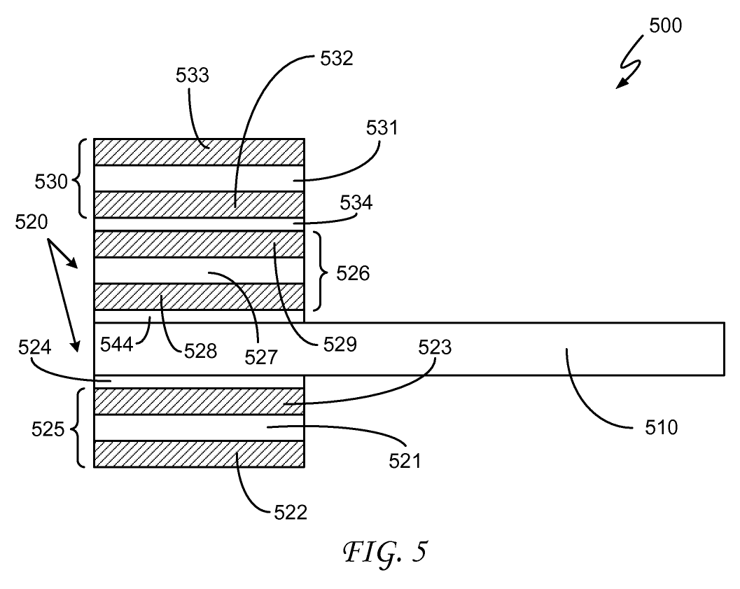

FIG. 5 is a side elevational view of a piezoelectric fan 500 according to an embodiment of the invention. As illustrated in FIG. 5, piezoelectric fan 500 comprises a blade 510, a piezoelectric actuator patch 520, and a piezoelectric sensor patch 530. Piezoelectric actuator patch 520 comprises a section 525 on a first side of blade 510 and a section 526 on a second side of blade 510. A piezoelectric actuator patch such as piezoelectric actuator patch 520 that has sections on both sides of an associated blade may be referred to as a bi-morph piezoelectric actuator patch. (Piezoelectric actuator patches like those described above that are wholly located on a single side of the associated blade may be referred to a mono-morph piezoelectric actuator patches.)

Section 525 of piezoelectric actuator patch 520 comprises a piezoelectric layer 521 located between an electrode 522 and an electrode 523. An adhesive layer 524 is located between electrode 523 and blade 510. Section 526 of piezoelectric actuator patch 520 comprises a piezoelectric layer 527 located between an electrode 528 and an electrode 529. An adhesive layer 544 is located between electrode 528 and blade 510. Similarly, piezoelectric sensor patch 530 comprises a piezoelectric layer 531 located between an electrode 532 and an electrode 533. An adhesive layer 534 is located between electrode 532 and electrode 529. As an example, piezoelectric layer 527 can be similar to piezoelectric layer 521, and electrodes 528 and 529 can be similar to electrodes 522 and 523. As another example, adhesive layer 544 can be similar to adhesive layer 524.

As illustrated, piezoelectric sensor patch 530 is located on a first side of blade 510 with section 526 of piezoelectric actuator patch 520, with section 525 of piezoelectric actuator patch 520 located on a second side of blade 510 opposite the first side. It should be understood that in a non-illustrated embodiment, piezoelectric sensor patch 530 can be located on the side of blade 510 that in the illustrated embodiment is occupied by section 525 of piezoelectric actuator patch 520, and vice versa. Similarly, in a non-illustrated embodiment, section 525 of piezoelectric actuator patch 520 can be located on the side of blade 510 that in the illustrated embodiment is occupied by section 526 of piezoelectric actuator patch 520, and vice versa.

As an example, blade 510, piezoelectric actuator patch 520, piezoelectric layer 521, electrode 522, electrode 523, adhesive layer 524, piezoelectric sensor patch 530, piezoelectric layer 531, electrode 532, electrode 533, and adhesive layer 534 can be similar to, respectively, blade 110, piezoelectric actuator patch 120, piezoelectric layer 121, electrode 122, electrode 123, adhesive layer 124, piezoelectric sensor patch 130, piezoelectric layer 131, electrode 132, electrode 133, and adhesive layer 134, all of which are shown in FIG. 1.

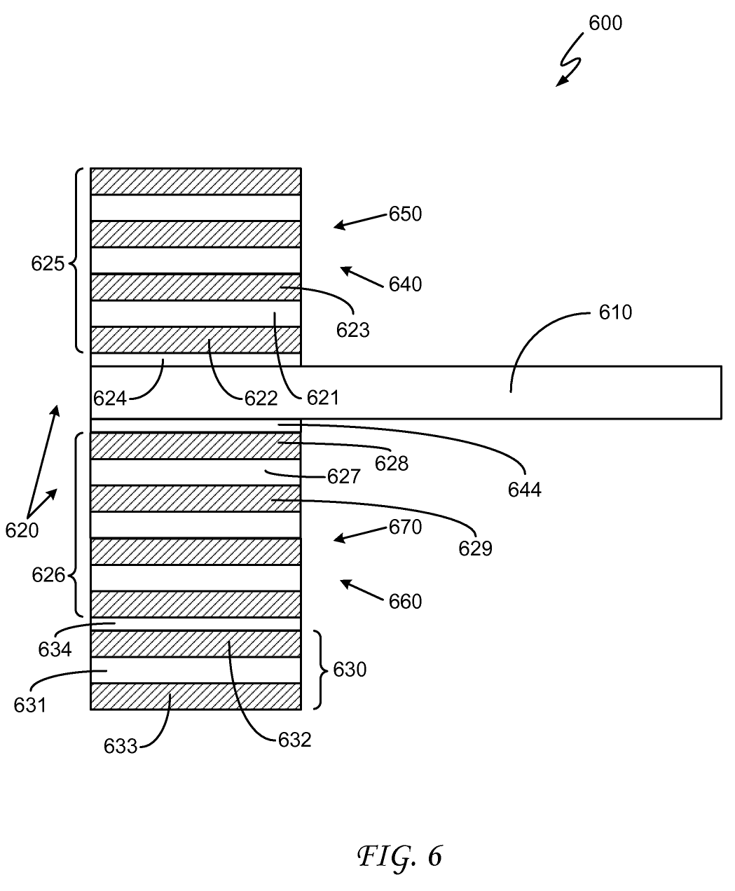

FIG. 6 is a side elevational view of a piezoelectric fan 600 according to an embodiment of the invention. As illustrated in FIG. 6, piezoelectric fan 600 comprises a blade 610, a piezoelectric actuator patch 620 adjacent to blade 610, and a piezoelectric sensor patch 630. Piezoelectric actuator patch 620 comprises a section 625 on a first side of blade 610 and a section 626 on a second side of blade 610.

Section 625 of piezoelectric actuator patch 620 comprises a piezoelectric layer 621 located between an electrode 622 and an electrode 623. An adhesive layer 624 is located between electrode 622 and blade 610. Piezoelectric layer 621 is one of a plurality 640 of piezoelectric layers that form a part of section 625 of piezoelectric actuator patch 620. Piezoelectric actuator patch 620 further comprises a plurality 650 of electrodes (a plurality that includes electrodes 622 and 623), and, as depicted in FIG. 6, each one of plurality 640 of piezoelectric layers in piezoelectric actuator patch 620 is located between a pair of electrodes of plurality 650 of electrodes. As an example, each one of plurality 640 of piezoelectric layers can be similar to piezoelectric layer 621, and each one of plurality 650 of electrodes can be similar to electrodes 622 and 623.

Section 626 of piezoelectric actuator patch 620 comprises a piezoelectric layer 627 located between an electrode 628 and an electrode 629. An adhesive layer 644 is located between electrode 628 and blade 610. As an example, piezoelectric layer 627 can be similar to piezoelectric layer 621, and electrodes 628 and 629 can be similar to electrodes 622 and 623. As another example, adhesive layer 644 can be similar to adhesive layer 624. Piezoelectric layer 627 is one of a plurality 660 of piezoelectric layers that form a part of section 626 of piezoelectric actuator patch 620. Piezoelectric actuator patch 620 further comprises a plurality 670 of electrodes (a plurality that includes electrodes 628 and 629), and, as depicted in FIG. 6, each one of plurality 660 of piezoelectric layers in piezoelectric actuator patch 620 is located between a pair of electrodes of plurality 670 of electrodes. As an example, each one of plurality 660 of piezoelectric layers can be similar to piezoelectric layer 627, and each one of plurality 670 of electrodes can be similar to electrodes 628 and 629.

Piezoelectric sensor patch 630 comprises a piezoelectric layer 631 located between an electrode 632 and an electrode 633. An adhesive layer 634 is located between electrode 632 and one of plurality 670 of electrodes of section 626. As illustrated, piezoelectric sensor patch 630 is located on a first side of blade 610 with section 626 of piezoelectric actuator patch 620, with section 625 of piezoelectric actuator patch 620 located on a second side of blade 610 opposite the first side. It should be understood that in a non-illustrated embodiment, piezoelectric sensor patch 630 can be located on the side of blade 610 that in the illustrated embodiment is occupied by section 625 of piezoelectric actuator patch 620, and vice versa. Similarly, in a non-illustrated embodiment, section 625 of piezoelectric actuator patch 620 can be located on the side of blade 610 that in the illustrated embodiment is occupied by section 626 of piezoelectric actuator patch 620, and vice versa.

As an example, blade 610, piezoelectric actuator patch 620, piezoelectric layer 621, electrode 622, electrode 623, adhesive layer 624, piezoelectric sensor patch 630, piezoelectric layer 631, electrode 632, electrode 633, and adhesive layer 634 can be similar to, respectively, blade 110, piezoelectric actuator patch 120, piezoelectric layer 121, electrode 122, electrode 123, adhesive layer 124, piezoelectric sensor patch 130, piezoelectric layer 131, electrode 132, electrode 133, and adhesive layer 134, all of which are shown in FIG. 1.

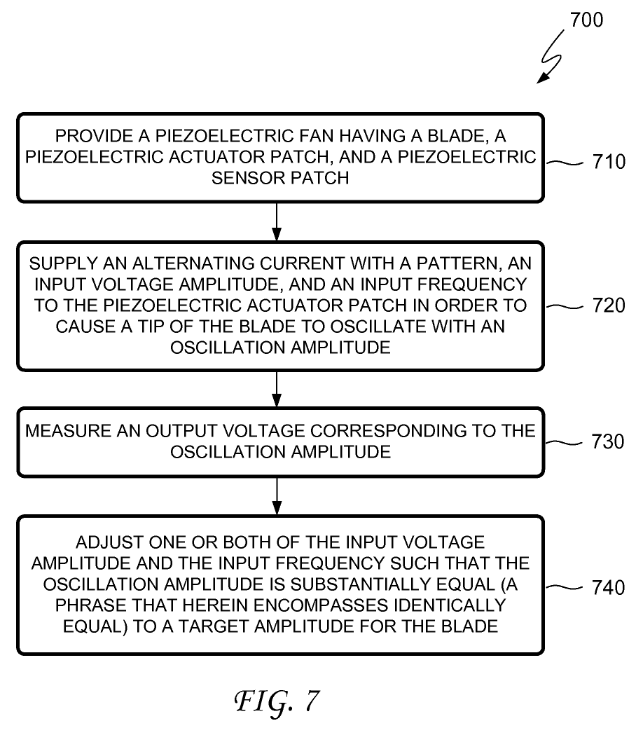

FIG. 7 is a flowchart illustrating a method 700 of cooling a microelectronic device according to an embodiment of the invention. A step 710 of method 700 is to provide a piezoelectric fan having a blade, a piezoelectric actuator patch, and a piezoelectric sensor patch. As an example, the piezoelectric fan can be similar to one or another of piezoelectric fans 100, 200, 300, 400, 500, and 600, shown in FIGS. 1, 2, 3, 4, 5, and 6, respectively.

A step 720 of method 700 is to supply an alternating current with a pattern, an input voltage amplitude, and an input frequency to the piezoelectric actuator patch in order to cause a tip of the blade to oscillate with an oscillation amplitude.

A step 730 of method 700 is to measure an output voltage corresponding to the oscillation amplitude. The measured output voltage is due to the strain on the piezoelectric sensor patch resulting from the deformation of the piezoelectric actuator patch, but such voltage can be correlated to the oscillation amplitude of the blade tip according to methods known in the art.

A step 740 of method 700 is to adjust one or both of the input voltage amplitude and the input frequency such that the oscillation amplitude is substantially equal (a phrase that herein encompasses identically equal) to a target amplitude for the blade. In one embodiment, step 740 comprises adjusting the input frequency such that it is substantially equal to a resonance frequency for the blade, and, after adjusting the input frequency, adjusting the input voltage amplitude such that the oscillation amplitude is substantially equal to the target amplitude for the blade. As known in the art, once the input frequency is set identical to the resonance frequency of the blade, the oscillation amplitude becomes largest for a given voltage amplitude. As an example, the target amplitude can be a specified amplitude that achieves a targeted cooling performance. This target amplitude may be, but is not necessarily, the maximum amplitude for the given voltage amplitude.

In one embodiment, step 740 further comprises adjusting one or both of the input voltage amplitude and the input frequency using an active feedback controller. As an example, the active feedback controller may adjust one or both of the input frequency and the input voltage amplitude based on an input signal generated by the piezoelectric sensor patch. As another example, the active feedback controller may adjust one or both of the input frequency and the input voltage amplitude using a voltage and frequency controller card.

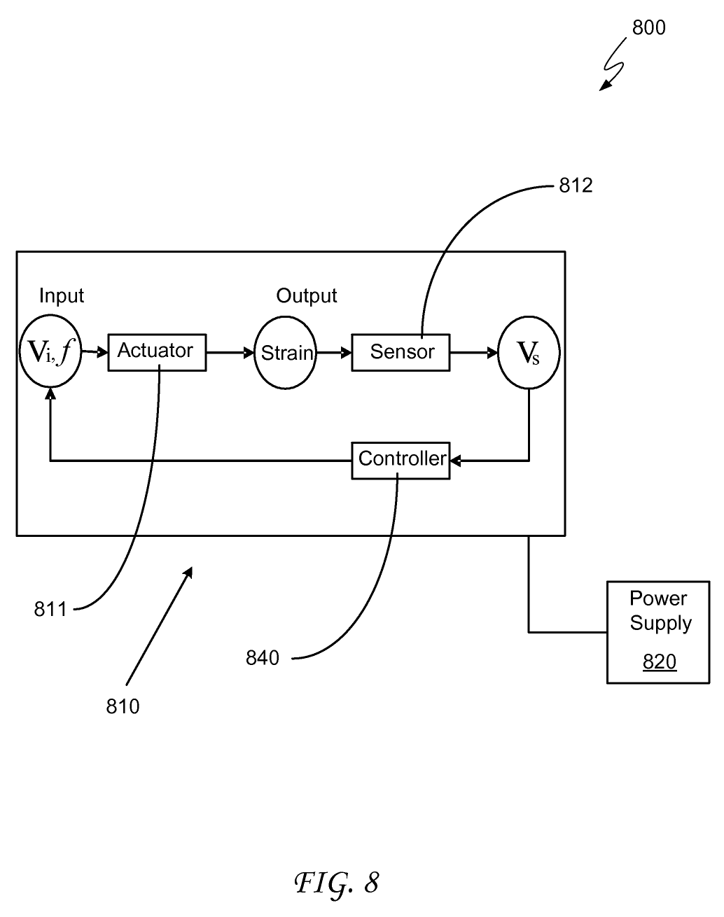

FIG. 8 is a chart illustrating an operation of a system 800 including a piezoelectric fan according to an embodiment of the invention. As illustrated in FIG. 8, system 800 comprises a piezoelectric fan 810, having a blade (not represented pictorially in FIG. 8), a piezoelectric actuator patch 811, and a piezoelectric sensor patch 812, a power supply 820, and an active feedback controller 840. In FIG. 8, Vi represents input voltage amplitude, f represents input frequency of alternating voltage, and VS represents amplitude of sensed voltage, meaning the amplitude of the voltage sensed by the piezoelectric sensor patch and transmitted as an input signal to the active feedback controller as discussed above.

As an example, piezoelectric fan 810 can be similar to one of piezoelectric fans 100, 200, 300, 400, 500, and 600, shown, respectively, in FIGS. 1, 2, 3, 4, 5, and 6. As another example, piezoelectric actuator patch 811, and piezoelectric sensor patch 812 can be similar to, respectively, piezoelectric actuator patch 120 and piezoelectric sensor patch 130, both of which are shown in FIG. 1.

Power supply 820 is capable of supplying an alternating voltage with a pattern, an input voltage amplitude, and an input frequency to piezoelectric actuator patch 811. Active feedback controller 840 is electrically coupled to piezoelectric fan 810 and is capable of receiving an input signal from piezoelectric sensor patch 812 and adjusting at least one of the input voltage amplitude and the input frequency in response to the input signal.

The amplitude of the piezoelectric fan is very dependent on the frequency of the electrical wave (i.e., the voltage pattern) applied to it, and that amplitude is maximized when the frequency of the applied voltage pattern equals the resonance frequency for the blade of the piezoelectric fan. In order for maximum performance to be achieved, the piezoelectric fan should be operated at resonance frequency at all times. However, the resonance frequency and blade tip amplitude are highly dependent on the conditions in which the fan operates, as mentioned above.

One environment in which embodiments of the piezoelectric fan may be used to advantage is an environment where the piezoelectric fan is used to enhance the forced convection supplied by axial fans. To this end a rake piezoelectric system, for example, may be used in conjunction with a parallel fin heat sink (and the axial fans) to provide more effective cooling. As mentioned, however, the piezoelectric fan's natural frequency and amplitude change as the flow rate provided by the axial fans changes. Thus, in order to achieve optimal performance, the frequency applied to the piezoelectric fan should be altered along with (and in response to) the changing flow rate. This is done using the active feedback controller to adjust the voltage pattern in response to the input signal from the piezoelectric sensor patch such that the frequency of the voltage pattern matches the resonance frequency. The amplitude of the voltage pattern may also be adjusted, if needed, to achieve desired performance parameters.

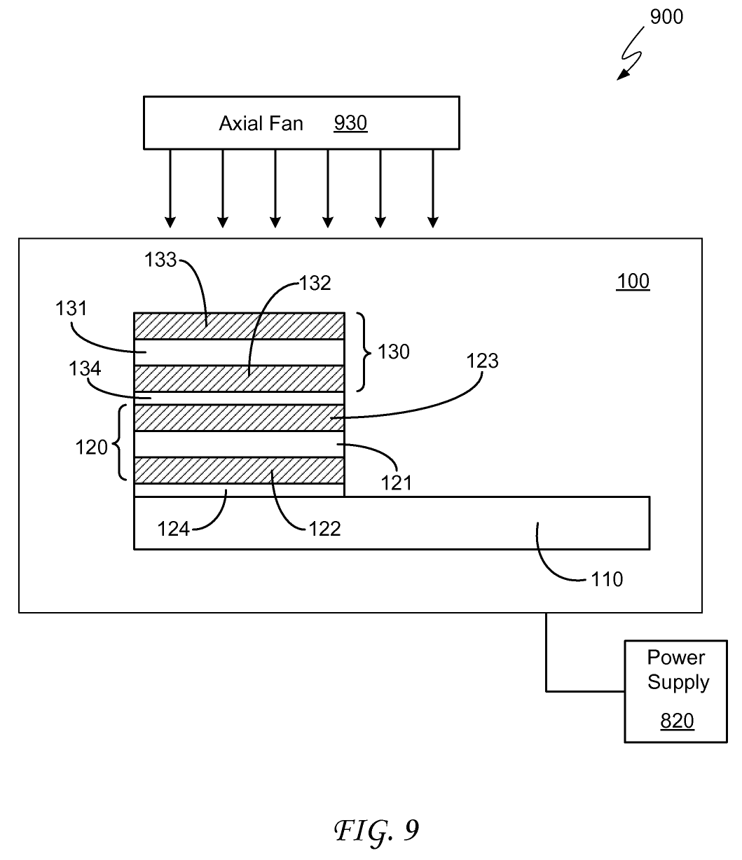

FIG. 9 is a schematic representation of a system 900 including an axial fan according to an embodiment of the invention. FIG. 9 depicts a block 910 containing a piezoelectric fan that is part of system 900. In the illustrated embodiment the piezoelectric fan is piezoelectric fan 100, but piezoelectric fan 100 could be replaced in system 900 by any other piezoelectric fan according to an embodiment of the invention. As shown, system 900 further comprises power supply 820 and an axial fan 930 that is capable of creating an axial air flow across at least a portion of piezoelectric fan 100. Axial fan 930 may enhance the cooling capacity of system 900 but, as mentioned above, the operation of piezoelectric fan 100 within the airflow of axial fan 930 may cause changes in the blade oscillation amplitude. As has been discussed, these may be compensated for or otherwise dealt with by piezoelectric fans according to embodiments of the invention.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the piezoelectric fans and associated methods and systems discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. A piezoelectric fan comprising:
a blade;
a piezoelectric actuator patch adjacent to the blade; and
a piezoelectric sensor patch adjacent to one of the piezoelectric actuator patch and the blade.

2. The piezoelectric fan of claim 1 wherein:
the piezoelectric sensor patch is capable of generating an electrical signal containing information relating to the piezoelectric fan.

3. The piezoelectric fan of claim 1 wherein:
the piezoelectric sensor patch comprises a first piezoelectric layer located between a first electrode and a second electrode; and
the piezoelectric actuator patch comprises a second piezoelectric layer located between a third electrode and a fourth electrode.

4. The piezoelectric fan of claim 3 wherein:
the piezoelectric sensor patch is located on a first side of the blade; and
the piezoelectric actuator patch is located on a second side of the blade.

5. The piezoelectric fan of claim 3 wherein:
the piezoelectric sensor patch and the piezoelectric actuator patch are both located on a first side of the blade.

6. The piezoelectric fan of claim 3 wherein:
the second piezoelectric layer is one of a plurality of piezoelectric layers of the piezoelectric actuator patch;
each one of the plurality of piezoelectric layers is located between a pair of electrodes of the piezoelectric actuator patch;
the piezoelectric sensor patch is located on a first side of the blade; and
the piezoelectric actuator patch is located on a second side of the blade.

7. The piezoelectric fan of claim 3 wherein:
the second piezoelectric layer is one of a plurality of piezoelectric layers of the piezoelectric actuator patch;
each one of the plurality of piezoelectric layers is located between a pair of electrodes of the piezoelectric actuator patch; and
the piezoelectric sensor patch and the piezoelectric actuator patch are both located on a first side of the blade.

8. The piezoelectric fan of claim 3 wherein:
the piezoelectric actuator patch comprises a first section on a first side of the blade and a second section on a second side of the blade; and
the piezoelectric sensor patch is located on the first side of the blade.

9. The piezoelectric fan of claim 3 wherein:
the piezoelectric actuator patch comprises a first section on a first side of the blade and a second section on a second side of the blade;
the second piezoelectric layer is one of a first plurality of piezoelectric layers of the first section of the piezoelectric actuator patch;
the piezoelectric actuator patch further comprises a third piezoelectric layer located between a fifth electrode and a sixth electrode;
the third piezoelectric layer is one of a second plurality of piezoelectric layers of the second section of the piezoelectric actuator patch;
each one of the first plurality of piezoelectric layers and each one of the second plurality of piezoelectric layers is located between a pair of electrodes of the piezoelectric actuator patch; and
the piezoelectric sensor patch is located on the first side of the blade.

10. A method of cooling a microelectronic device, the method comprising:
providing a piezoelectric fan having a blade, a piezoelectric actuator patch, and a piezoelectric sensor patch;
supplying an alternating voltage pattern having an input voltage amplitude and an input frequency to the piezoelectric actuator patch in order to cause a tip of the blade to oscillate with an oscillation amplitude;
measuring an output voltage corresponding to the oscillation amplitude; and
adjusting one or both of the input voltage amplitude and the input frequency such that the oscillation amplitude is substantially equal to a target amplitude for the blade.

11. The method of claim 10 wherein:
adjusting one or both of the input voltage amplitude and the input frequency comprises:
adjusting the input frequency such that it is substantially equal to a resonance frequency for the blade; and
after adjusting the input frequency, adjusting the input voltage amplitude such that the oscillation amplitude is substantially equal to the target amplitude for the blade.

12. The method of claim 11 wherein:
adjusting one or both of the input voltage amplitude and the input frequency further comprises adjusting one or both of the input voltage amplitude and the input frequency using an active feedback controller.

13. The method of claim 12 wherein:
the active feedback controller adjusts one or both of the input frequency and the input voltage amplitude based on an input signal generated by the piezoelectric sensor patch.

14. The method of claim 13 wherein:
the active feedback controller adjusts one or both of the input frequency and the input voltage amplitude using a voltage and frequency controller card.

15. A system comprising:
a piezoelectric fan having a blade, a piezoelectric actuator patch, and a piezoelectric sensor patch;
a power supply capable of supplying an input voltage amplitude and an input frequency to the piezoelectric actuator patch;
an axial fan capable of creating an axial air flow across at least a portion of the piezoelectric fan; and
an active feedback controller electrically coupled to the piezoelectric fan and capable of receiving an input signal from the piezoelectric sensor patch and adjusting at least one of the input voltage amplitude and the input frequency in response to the input signal.

16. The system of claim 15 wherein:
the piezoelectric sensor patch comprises a first piezoelectric layer located between a first electrode and a second electrode; and
the piezoelectric actuator patch comprises a second piezoelectric layer located between a third electrode and a fourth electrode.

17. The system of claim 15 wherein:
the piezoelectric sensor patch is located on a first side of the blade; and
the piezoelectric actuator patch is located on a second side of the blade.

18. The system of claim 15 wherein:
the piezoelectric sensor patch and the piezoelectric actuator patch are both located on a first side of the blade.

19. The system of claim 15 wherein:
the piezoelectric actuator patch comprises a plurality of piezoelectric layers.

20. The system of claim 19 wherein:
the piezoelectric actuator patch comprises a first section on a first side of the blade and a second section on a second side of the blade; and
a first one of the plurality of piezoelectric layers forms a part of the first section and a second one of the plurality of piezoelectric layers forms a part of the second section.
